(19) United States
(12) Patent Application Publication
(10) Pub. No.: US 2009/0223653 A1
(43) Pub. Date: Sep. 10, 2009

(54) Method for Operating a Heat Dissipation System Background of the Invention

(75) Inventors: Hsin-Yi Li, Taipei (TW); Po-Huan Chen, Taipei (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: ASUSTEK COMPUTER INC., Taipei (TW)

(21) Appl. No.: 12/358,502

(22) Filed: Jan. 23, 2009

(30) Foreign Application Priority Data
Mar. 4, 2008 (TW) 97107549

(51) Int. Cl. H01L 23/467

(52) U.S. Cl. 165/121

(57) ABSTRACT

A method for operating a heat dissipation system is described as follows. Starting a first active heat dissipation device to dissipate heat of a heat source. After the first active heat dissipation device operates for a first predetermined period of time, starting the second active heat dissipation device to dissipate the heat of the heat source. Stopping operation of the first active heat dissipation device.

### RELATED APPLICATIONS

This application claims priority to Taiwan Application Serial Number 97107549, filed Mar. 4, 2008, which are herein incorporated by reference.

### BACKGROUND OF THE INVENTION

1. Field of the Invention

The invention is related to a heat dissipation system and, more particularly, to a heat dissipation system which can generate forced convection.

2. Description of the Related Art

A conventional heat dissipation system often includes a device which can generate forced convection to increase heat dissipation efficiency. For example, the heat dissipation system can include heat dissipation fins and a fan, and can increase heat dissipation efficiency by the forced convection generated by the fan. Therefore, the fan plays an important role in heat dissipation system. Once the fan stops working, the heat dissipation system cannot take away a great quantity of heat from the system. The minor result is the poor operation of the components, and the serious result is the burning out of the components.

### SUMMARY OF THE INVENTION

Therefore, an objective of the invention is to provide a heat dissipation system operating method.

To achieve the above objectives, a heat dissipation system operating method is provided. The heat dissipation system operating method is applied to a heat dissipation system including a first active heat dissipation device and a second active heat dissipation device. The method includes the steps of: starting the first active heat dissipation device to dissipate heat of a heat source; after the first active heat dissipation device operates for a first predetermined period of time, starting the second active heat dissipation device to dissipate the heat of the heat source; and stopping operation of the first active heat dissipation device.

By starting and stopping a fluid driving device alternately, the heat dissipation system operating method according to the invention makes forced heat convection exist any time in the heat dissipation system and also prolongs life of the fluid driving device.

### BRIEF DESCRIPTION OF THE DRAWINGS

These and other features, aspects, and advantages of the present invention will become better understood with regard to the following description, appended claims, and accompanying drawings, wherein:

FIG. 1 is a diagram showing steps of a method for operating a heat dissipation system according to one preferred embodiment of the invention;

FIG. 2 is a diagram showing an air-cooling active heat dissipation device according to one preferred embodiment of the invention;

FIG. 3 is a diagram showing a liquid-cooling active heat dissipation device according to one preferred embodiment of the invention;

FIG. 4 is a structural diagram showing a mixed active heat dissipation device combining air-cooling and liquid-cooling according to one preferred embodiment of the invention.

### DETALED DESCRPTION OF THE EMBODIMENTS

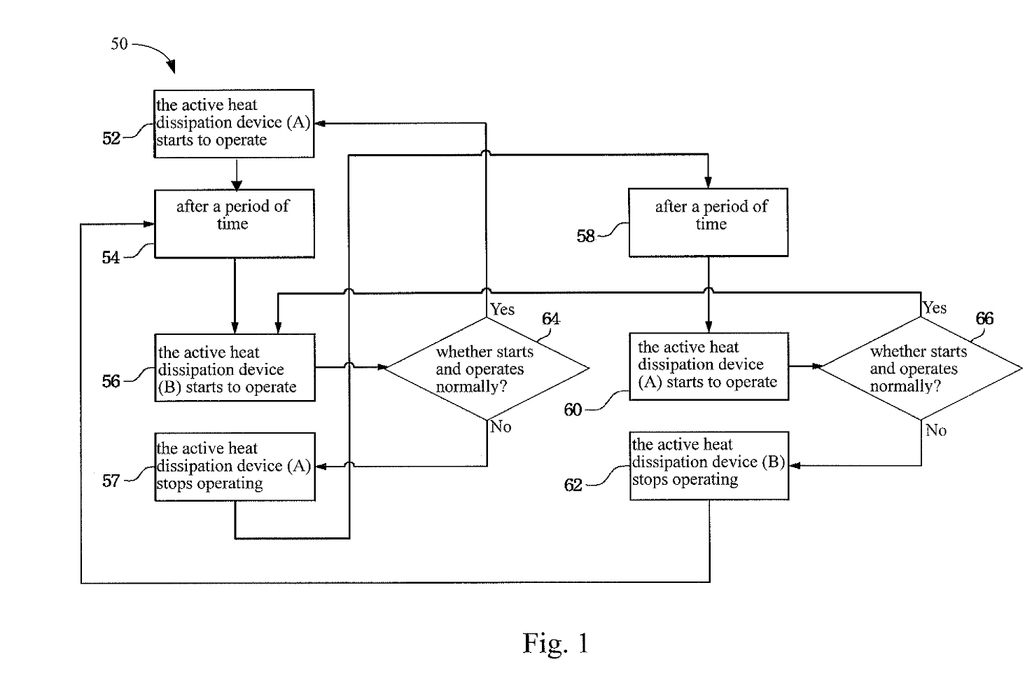

FIG. 1 is a diagram showing steps of a method for operating a heat dissipation system according to one preferred embodiment of the invention. By starting and stopping multiple active heat dissipation devices continuously and alternately, the heat dissipation system operating method 50 makes forced heat convection exist any time in the heat dissipation system. After the active heat dissipation device (A) operates for a predetermined period of time (steps 52 and 54), the active heat dissipation device (B) starts to operate (step 56). After the heat dissipation system confirms the normal start and the normal operation of the active heat dissipation device (B) starts (step 64), the active heat dissipation device (A) stops operating (step 57). Next, after the active heat dissipation device (B) operates for a predetermined period of time (step 58), the active heat dissipation device (A) starts to operate (step60). After the heat dissipation system confirms the normal start and the normal operation of the active heat dissipation device (A) (step 66), the active heat dissipation device (B) stops operating (step 62). The active heat dissipation device (A) and the active heat dissipation device (B) are started and stopped continuously and alternately, such that forced heat convection exists any time in the heat dissipation system and lives of the active heat dissipation device (A) and the active heat dissipation device (B) are prolonged. Operating time of the active heat dissipation device (A) and the active heat dissipation device (B) can be the same or be different. In the above embodiment, the heat dissipation system includes two active heat dissipation devices, but it is obvious that three or more than three active heat dissipation devices can also be implemented according to the above method.

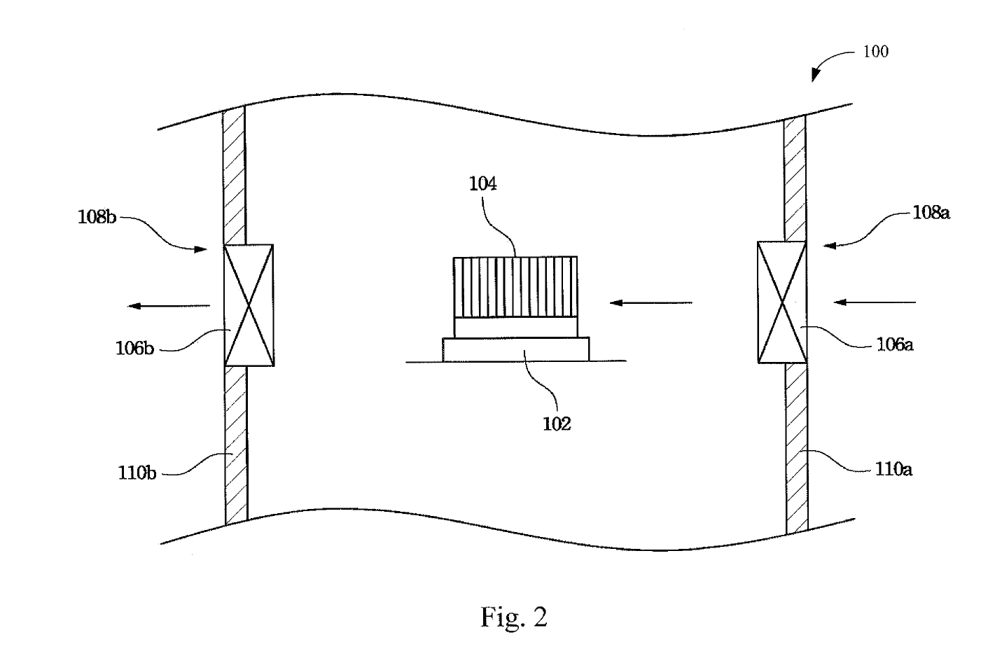

FIG. 2 is a diagram showing an air-cooling active heat dissipation device according to one preferred embodiment of the invention. The air-cooling active heat dissipation device 100 includes a heat dissipation fin 104 and two fans 106a and 106b. The heat dissipation fin 104 is pasted on a heat source 102, to accelerate dissipating speed of heat generated thereof. The fans 106a and 106b are disposed in an air inlet 108a (on the housing wall 110a) and an air outlet 108b (on the housing wall 110b) respectively. The fan 106a blows air towards the heat dissipation fin 104 through the air inlet 108a, and the fan 106b exhausts the air out of the system through the air outlet 108b. By operation of either the fan 106a or the fan 106b, the air can be drawn in through the air inlet 108a, introduced towards the heat dissipation fin 104, and hotter air can be exhausted through the air outlet 108b. The above heat dissipation system operating method 50 can be applied to the air-cooling active heat dissipation device 100 (for example, the active heat dissipation device (A) is the fan 106a, and the active heat dissipation device (B) is the fan 106b), and the fans 106a and 106b are started and stopped continuously and alternately according to the principle of the heat dissipation system operating method 50.

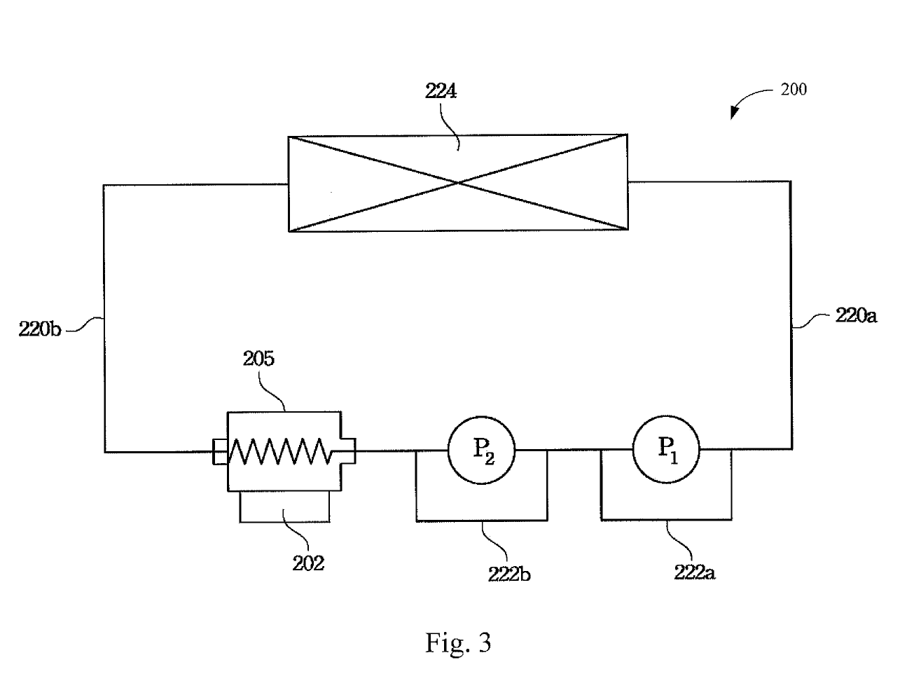

FIG. 3 is a diagram showing a liquid-cooling active heat dissipation device according to one preferred embodiment of the invention. The liquid-cooling active heat dissipation device 200 includes a cooler 224, an inlet pipe 220a, an outlet pipe 220b, a heat dissipation plate 205, and two driving groups. The heat dissipation plate 205 is pasted on a heat source 202 to accelerate dissipating speed of heat generated thereof. The two driving groups drive cooling media to circulate in the inlet pipe 220a and the outlet pipe 220b. When passing through the heat dissipation plate 205, the cooling media absorb the heat of the heat dissipation plate 205. When the cooling media pass through the cooler 224, the heat taken from the heat dissipation plate 205 by the cooling media is dissipated. The driving groups include bumps and side flowing pipes. When the pump (P1 or P2) stops working, the cooling media can not circulate through the pump (P1 or P2) and will detour round the side flowing pipe (222a or 222b). The above heat dissipation system operating method 50 also can be applied to the liquid-cooling active heat dissipation device 200 (for example, the active heat dissipation device (A) is the pump P1, and the active heat dissipation device (B) is the pump P2), and the pumps P1 and P2 are started and stopped continuously and alternately according to the principle of the heat dissipation system operating method 50.

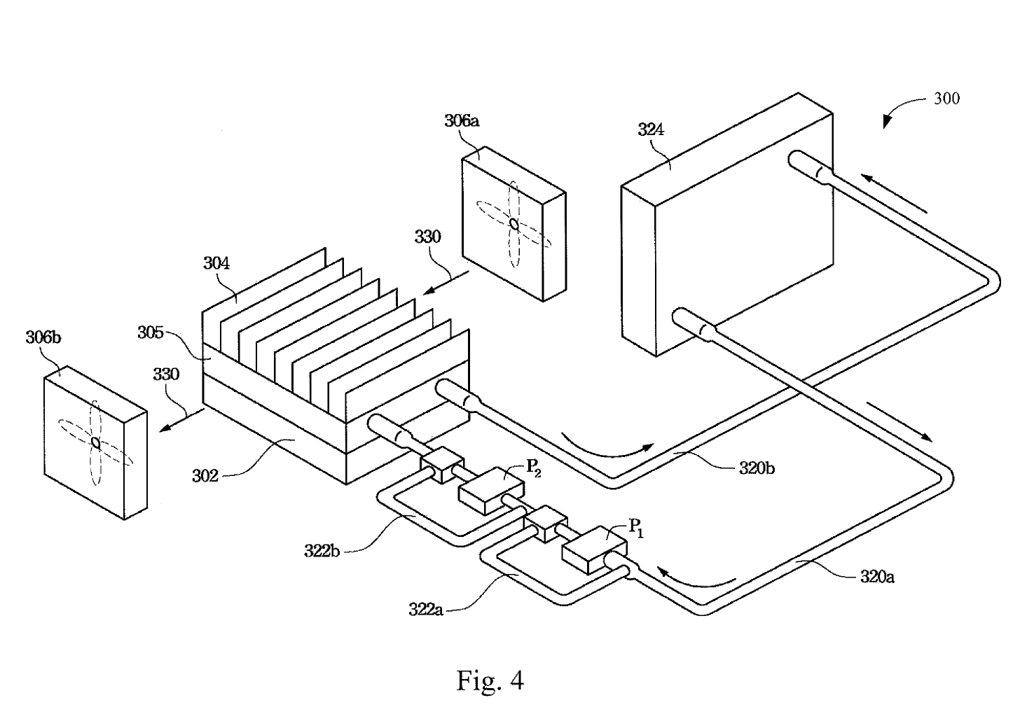

FIG. 4 is a structural diagram showing a mixed active heat dissipation device combining air-cooling and liquid-cooling according to one preferred embodiment of the invention. The active heat dissipation device 300 is a mixed active heat dissipation device combining air-cooling and liquid-cooling, and includes a heat dissipation plate 305 pasted on a heat source 302 to accelerate dissipating speed of heat generated thereof. The heat dissipation plate 305 can transmit the heat to a heat dissipation fin 304, and forced convection (such as airflow along direction 330) generated by the fans 306a and 306b can further accelerate the dissipating speed of heat. Simultaneously, the heat dissipation plate 305 also includes winded pipes (refer to the heat dissipation plate 205 in FIG. 3) for taking the heat away by the circulated cooling media. The cooling media can be introduced into the heat dissipation plate 305 by an inlet pipe 320a and derived from the heat dissipation plate 305 by an outlet pipe 320b. After passing through a cooler 324, the heat taken by the cooling media from the heat dissipation plate 305 is dissipated herein. Driving groups include pumps and side flowing pipes. When the pump (P1 or P2) stops working, the cooling media can not circulate through the pump (P1 or P2) and will detour round the side flowing pipe (322a or 322b). The above heat dissipation system operating method 50 also can be applied to the active heat dissipation device 300 The air-cooling active heat dissipation device and the liquid-cooling active heat dissipation device are started and stopped alternately according to the principle of the heat dissipation system operating method 50. When the air-cooling active heat dissipation device drives gas to flow, the fans 306a and 306b are started and stopped alternately according to the principle of the heat dissipation system operating method 50. When the liquid-cooling active heat dissipation device drives the cooling media to flow, the pumps P1 and P2 also are started and stopped alternately according to the principle of the heat dissipation system operating method 50.

By starting and stopping a fluid driving device alternately, the heat dissipation system operating method according to the invention makes forced heat convection exist any time in the heat dissipation system and also prolongs life of the fluid driving device.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A method for operating a heat dissipation system including a first active heat dissipation device and a second active heat dissipation device, the method comprising the steps of:
starting the first active heat dissipation device to dissipate heat of a heat source;
after the first active heat dissipation device operates for a first predetermined period of time, starting the second active heat dissipation device to dissipate the heat of the heat source; and
stopping the operation of the first active heat dissipation device.

2. The method according to claim 1, wherein the first active heat dissipation device and the second active heat dissipation device are both air-driving devices.

3. The method according to claim 2, wherein the air-driving devices are fans.

4. The method according to claim 1, wherein the first active heat dissipation device and the second active heat dissipation device are both liquid-driving devices.

5. The method according to claim 4, wherein the first active heat dissipation device and the second active heat dissipation device are both pumps.

6. The method according to claim 1, wherein the first active heat dissipation device is an air-cooling active heat dissipation device and the second active heat dissipation device is a liquid-cooling active heat dissipation device.

7. The method according to claim 6, wherein the air-cooling active heat dissipation device and the liquid-cooling active heat dissipation device share a heat dissipation plate pasted on the heat source.

8. The method according to claim 7, wherein the air-cooling active heat dissipation device further comprises a heat dissipation fin and two fans, the heat dissipation fin is pasted on the heat dissipation plate, and one of the fans drives air towards the heat dissipation fin.

9. The method according to claim 7, wherein the liquid-cooling active heat dissipation device drives cooling media to pass through the heat dissipation plate.

10. The method according to claim 9, wherein the liquid-cooling active heat dissipation device further comprises an inlet pipe, an outlet pipe and two pumps, and the two pumps drive the cooling media to flow into the heat dissipation plate via the inlet pipe and flow out of the heat dissipation plate via the outlet pipe.

11. The method according to claim 10, further comprising the step of:
when the air-cooling active heat dissipation device drives the gas to flow, starting and stopping operation of the two fans alternately.

12. The method according to claim 10, further comprising the step of:
when the liquid-cooling active heat dissipation device drives the cooling media to flow, starting and stopping operation of the two pumps alternately.

13. The method according to claim 1, further comprising the steps of:
after the second active heat dissipation device operates for a second predetermined period of time, starting the first active heat dissipation device; and
stopping operation of the second active heat dissipation device.

14. The method according to claim 13, wherein before the step of stopping the operation of the second active heat dissipation device, the method further comprises a step of confirming the normal operation of the first active heat dissipation device.

15. The method according to claim 1, wherein before the step of stopping operation of the first active heat dissipation device, the method further comprises a step of confirming the normal operation of the second active heat dissipation device.
